(19) United States
(12) Patent Application Publication
(10) Pub. No.: US 2022/0147458 A1
(43) Pub. Date: May 12, 2022

(54) SEMICONDUCTOR DEVICE

(71) Applicant: SAMSUNG ELECTRONICS CO., LTD., SUWON-SI (KR)

(72) Inventors: JEONG HO LEE, GWACHEON-SI (KR); DAE HUI KIM, GUMI-SI (KR); YOUN HO JEON, GIMHAE-SI (KR); HYEOK JUN CHOE, HWASEONG-SI (KR)

(21) Appl. No.: 17/394,183

(22) Filed: Aug. 4, 2021

(30) Foreign Application Priority Data
Nov. 11, 2020 (KR) 10-20200150268

(51) Int. Cl. G06F 12/0817

(52) U.S. Cl. CPC G06F 12/0828; G06F 2212/621

(57) ABSTRACT

A semiconductor device includes a device memory, and a device coherency engine (DCOH) that shares a coherency state of the device memory based on data in a host device and a host memory. A power supply of device memory is dynamically adjusted based on the coherency state.

### CROSS-REFERENCE TO RELATED APPLICATION

This application claims priority under 35 U.S.C. 119 from Korean Patent Application No. 10-2020-0150268, filed on Nov. 11, 2020 in the Korean Intellectual Property Office, the contents of which are herein incorporated by reference in their entirety.

### BACKGROUND

### 1. Technical Field

Embodiments of the present disclosure are directed to a semiconductor device. In particular, embodiments of the present disclosure are directed to a semiconductor device that uses a Compute express Link (CXL) interface.

### 2. Discussion of the Related Art

Technologies such as artificial intelligence (AI), big data, and edge computing, require faster processing of large amounts of data. In other words, high-bandwidth applications that perform complex computation require faster data processing and more efficient memory accesses.

However, host devices, such as computing devices such as CPUs and GPUs are mostly connected to semiconductor devices that include memory through a PCIe protocol, which has a relatively low bandwidth and long delays, and issues related to coherency and memory sharing with the semiconductor devices can occur.

### SUMMARY

Embodiments of the present disclosure provide a semiconductor device that dynamically varies power usage depending on memory usage to efficiently use the power.

An exemplary embodiment of the present disclosure provides a semiconductor device that includes a device memory and a device coherency engine (DCOH) that shares a coherency state of the device memory based on data in a host device and a host memory. A power supply of the device memory is dynamically adjusted based on the coherency state.

An exemplary embodiment of the present disclosure provides a computing system that includes a semiconductor device connected to a host device through a Compute eXpress Link (CXL) interface. The semiconductor device includes at least one accelerator memory that stores data and an accelerator that shares a coherency state of the at least one accelerator memory with the host device. A power supply to the accelerator memory is dynamically controlled by the semiconductor device according to the coherency state.

An exemplary embodiment of the present disclosure provides computing system that includes a semiconductor device connected to a host device. The semiconductor device includes a memory device that includes at least one working memory that stores data and a memory controller that shares a coherency state of the working memory with the host device. A power supply to the working memory is dynamically controlled by the semiconductor device according to the coherency state.

### BRIEF DESCRIPTION OF THE DRAWINGS

FIGS. 1 and 2 are block diagrams of a semiconductor device connected to a host device according to some embodiments.

FIG. 3 illustrates the coherency states of a device memory in a semiconductor device.

FIGS. 4 to 7 are tables of metadata indicative of the coherency state of FIG. 3.

FIGS. 8 and 9 are flowcharts of an operation between a host device and a semiconductor device, according to some embodiments.

FIG. 10 is a flowchart of an operation between a host device and a semiconductor device, according to some embodiments.

FIGS. 11 to 14 illustrate a power operation policy of a semiconductor device, according to some embodiments.

FIG. 15 is a block diagram of a system according to another exemplary embodiment of the present disclosure.

FIGS. 16A and 16B are block diagrams of examples of a system according to an exemplary embodiment of the present disclosure.

FIG. 17 is a block diagram of a data center that includes a system according to an exemplary embodiment of the present disclosure.

### DETAILED DESCRIPTION OF EMBODIMENTS

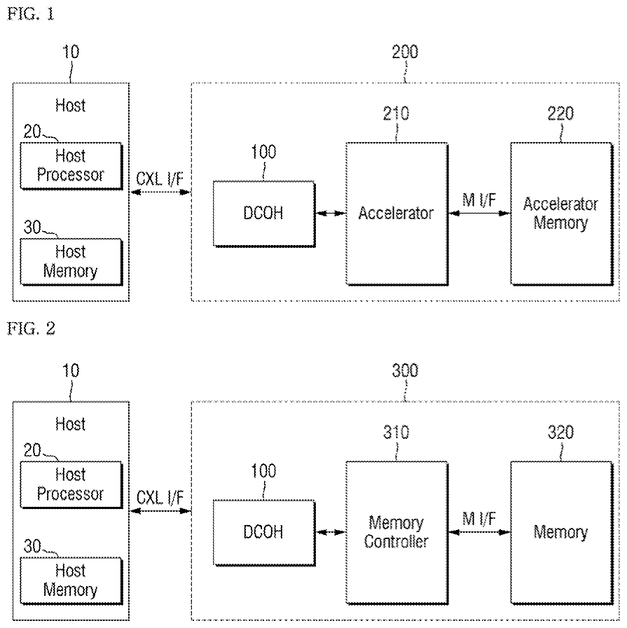

FIGS. 1 and 2 are block diagrams of a semiconductor device connected to a host device according to some embodiments. The semiconductor device and the host device together constitute a computing system.

In some embodiments, a host device 10 corresponds to one of a central processing unit (CPU), a graphic processing unit (GPU), a neural processing unit (NPU), an FPGA, a processor, a microprocessor, or an application processor (AP), etc. According to some embodiments, the host device 10 is implemented as a system-on-a-chip (SoC). For example, the host device 10 may be a mobile system such as a portable communication terminal (mobile phone), a smart phone, a tablet personal computer, a wearable device, a healthcare device, or an Internet of Things (IoT) device. The host device 10 may also be one of a personal computer, a laptop computer, a server, a media player, or an automotive device such as a navigation system. In addition, the host device 10 includes a communication device (not shown) that can transmit and receive signals between other devices according to various communication protocols. The communication device can perform wired or wireless communication, and may be implemented with, for example, an antenna, a transceiver, and/or a modem. The host device 10 can perform, for example, an Ethernet or wireless communication through the communication device.

According to some embodiments, the host device 10 includes a host processor 20 and a host memory 30. The host processor 20 controls the overall operation of the host device 10, and the host memory 30 is a working memory and stores instructions, programs, data, etc., used for the operation of the host processor 20.

According to some embodiments, FIG. 1 shows a semiconductor device 200 that uses a CXL interface and that includes an accelerator 210 and an accelerator memory 220. According to some embodiments, FIG. 2 shows a semiconductor device 300 that uses a CXL interface and that includes a memory controller 310 and a working memory 320.

In FIG. 1, according to some embodiments, the accelerator 210 is a module that performs complex computation. The accelerator 210 is a workload accelerator, and may be, for example, a graphic processing unit (GPU) that performs deep learning computation for artificial intelligence, a central processing unit (CPU) that supports networking, a neural processing unit (NPU) that performs neural network computation, etc. Alternatively, the accelerator 210 may be a field programmable gate array (FPGA) that performs preset computations. The FPGA may, for example, reset all or part of the operation of the device and may adaptively perform complex computations such as artificial intelligence computations, deep learning computations, or image processing computations.

According to some embodiments, the accelerator memory 220 may be an internal memory disposed in the semiconductor device 200 that includes the accelerator 210, or may be an external memory device connected to the semiconductor device 200 that includes the accelerator 210.

In FIG. 2, according to some embodiments, the memory controller 310 controls the overall operation of the working memory 320 and, for example, manages memory access. According to an embodiment, the working memory 320 is a buffer memory of the semiconductor device 300.

According to some embodiments, the accelerator memory 220 and the working memory 320 are buffer memories. In addition, according to some embodiments, the accelerator memory 220 and the working memory 320 are volatile memories and include at least one of a cache, a read-only memory (ROM), a programmable read only memory (PROM), an erasable PROM (EPROM), an electrically erasable programmable read-only memory (EEPROM), a phase-change RAM (PRAM), a flash memory, a static RAM (SRAM), or a dynamic RAM (DRAM). According to some embodiments, the accelerator memory 220 and the working memory 320 may, as internal memories, be integrated in the accelerator 210 or the memory controller 310, or may exist separately from the accelerator 210 and the memory controller 310. Programs, commands, or preset information related to the operation or state of the accelerator 210 or the memory controller 310 are stored in the accelerator memory 220 and the working memory 320. For simplicity of description, the accelerator memory 220 and the working memory 320 will be referred to in the present disclosure as a device memory.

According to some embodiments, the host device 10 is connected to the semiconductor device 200, 300 through the CXL interface to control the overall operation of the semiconductor device 200, 300. The CXL interface allows the host device and the semiconductor device to reduce the overhead and latency and to share the space of the host memory and the device memory in a heterogeneous computing environment in which the host device 10 and the semiconductor device 200, 300 operate together, due to data compression and encryption, and special workloads such as artificial intelligence (AI). The host device 10 and the semiconductor device 200, 300 maintain memory coherency between the accelerator and the CPU with a very high bandwidth through the CXL interface.

For example, according to some embodiments, the CXL interface between different types of devices allows the host device 10 to use the device memory 220, 320 in the semiconductor device 200, 300 as a working memory of the host device to support cache coherency, and allows the device memory 220, 320 to access data through Load/Store memory commands.

The CXL interface includes three sub-protocols, i.e., CXL.io, CXL.cache, and CXL.mem. CXL.io uses a PCIe interface and is used for device discovery, interrupt management, providing access by registers, initialization processing, signal error processing, etc., in the system. CXL.cache is used when a computing device such as the accelerator in the semiconductor device accesses the host memory of the host device. CXL.mem is used when the host device accesses the device memory in the semiconductor device.

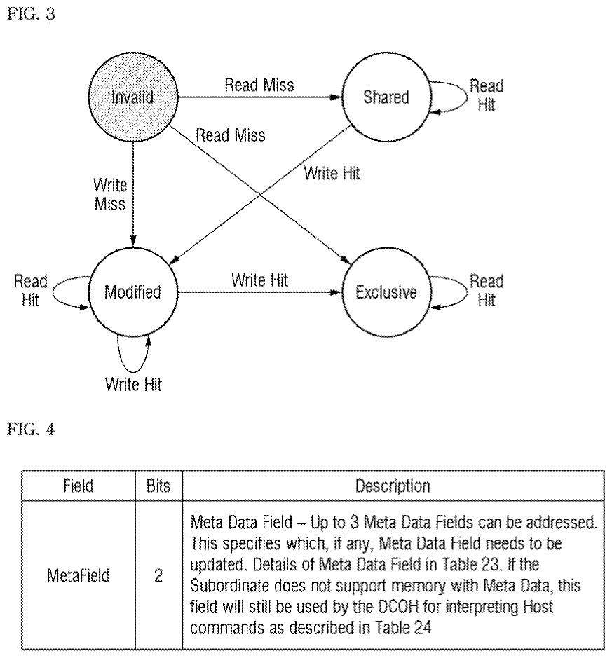

According to some embodiments, the semiconductor device 200, 300 includes a device coherency engine (DCOH) 100. The DCOH 100 manages data coherency between the host memory 30 and the device memory 220, 320 in the CXL.mem sub-protocol described above. The DCOH 100 includes a coherency state in a request and a response transmitted and received between the host device 10 and the semiconductor device 200, 300 to manage data coherency in real time. The DCOH 100 will be described below with reference to FIGS. 3 to 12.

According to some embodiments, the DCOH 100 is implemented separately from the accelerator 210 or the memory controller 310. Alternatively, according to some embodiments, the DCOH 100 is incorporated into the accelerator 210 or the memory controller 310.

According to some embodiments, the host device 10 transmits a request that includes one or more commands (CMD) related to data and memory management, and receives a response to the transmitted request.

According to some embodiments, the memory controller 310 of FIG. 2 is connected to the working memory 320 and can temporarily store in the working memory 320 data received from the host device 10 and then provide the data to a nonvolatile memory device. In addition, the memory controller 310 can provide to the host device 10 data read from the nonvolatile memory device.

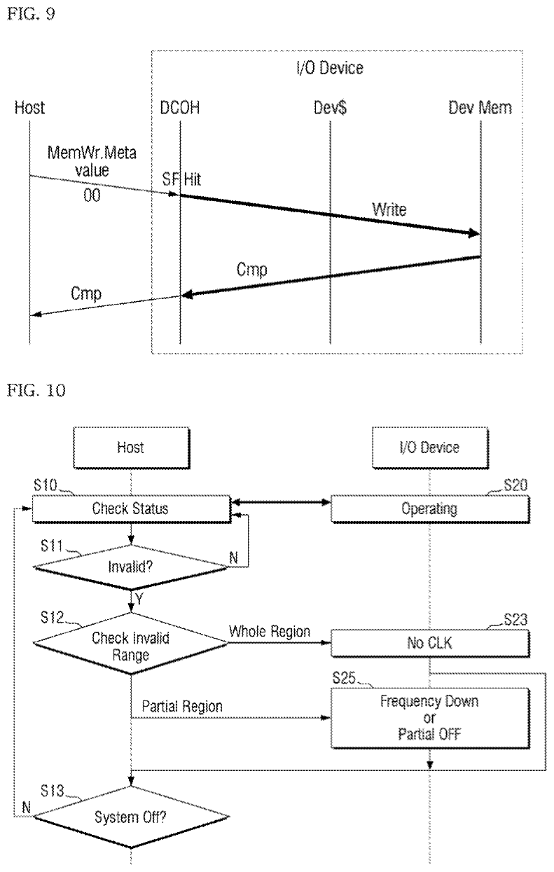

FIG. 3 illustrates the coherency states of a device memory in a semiconductor device. FIGS. 4 to 7 are tables of metadata indicative of the coherency state of FIG. 3. FIGS. 8 and 9 are flowcharts of an operation between a host device and a semiconductor device, according to some embodiments.

Referring to FIG. 3, according to some embodiments, the device memory 220, 320 included in the semiconductor device 200, 300 includes a plurality of coherency states.

According to some embodiments, the coherency states of the device memory 220, 320 include a MESI protocol, i.e., an invalid state, a shared state, a modified state, and an exclusive state.

According to some embodiments, the invalid state refers to a state in which data in the host memory 30 is modified, so that data in the device memory 220, 320 is no longer valid. The shared state refers to a state in which data in the device memory 220, 320 is the same as data in the host memory 30. The modified state refers to a state in which data in the device memory 220, 320 is modified. The exclusive state refers to a state in which data is present in only one of the host memory 30 or the device memory 220, 320.

According to some embodiments, in a read miss, after the device memory 220, 320 first reads data from the host memory 30, if the read data is deleted or modified in the host memory 30, the DCOH 100 sets the state of the device memory 220, 320 to the exclusive state.

Alternatively, according to some embodiments, in a read miss where the device memory 220, 320 reads data from the host memory 30, if the host memory 30 continuously keeps the read data, the DCOH 100 sets the coherency state of the device memory to the shared state.

According to some embodiments, in a write hit, if data stored in the device memory 220, 320 is updated, the DCOH 100 sets the state of the device memory 220, 320 to the modified state.

According to some embodiments, in a read miss, after the host device 10 reads data from the device memory 220, 320, if the read data is deleted in the device memory 220, 320, the DCOH 100 may set the state of the device memory 220, 320 to the invalid state.

According to some embodiments, in a read miss where a second device memory 220, 320 reads from the host memory 30 the same data as that of a first device memory 220, 320 of the plurality of semiconductor devices, the DCOH 100 sets the coherency state of the first device memory to the shared state, and then sets the coherency state of the second device memory to the shared state.

According to some embodiments, when, in one of the first device memory 220, 320 or the second device memory 220, 320, such as the first device memory, data that has been shared between them is modified, since data in the other (second) device memory is no longer valid, the DCOH 100 sets the first device memory to the modified state and the second device memory to the invalid state.

According to some embodiments, when the first device memory is in the modified state as described above, if data in the first device memory is changed again, i.e., the data is changed according to the write hit, then the DCOH 100 maintains the first device memory in the modified state.

According to some embodiments, the coherency state of the device memory is indicated in a metafield flag of a request transmitted from the host device 10 to the semiconductor device 200, 300. In an example shown in FIG. 4, the metafield flag is 2 bits, and even if the semiconductor device 200, 300 does not support metadata, the DCOH 100 translates a command from the host device 10 requesting the coherency state of the device memory 220, 320 and transmits a request to the semiconductor device 200, 300. In an example shown in FIG. 6, the metafield flag is 2 bits, and if the semiconductor device 200, 300 supports metadata, the DCOH 100 includes in a request, as the metafield flag, a command from the host device 10 requesting the coherency state of the device memory 220, 320, and transmits the request to the semiconductor device 200, 300.

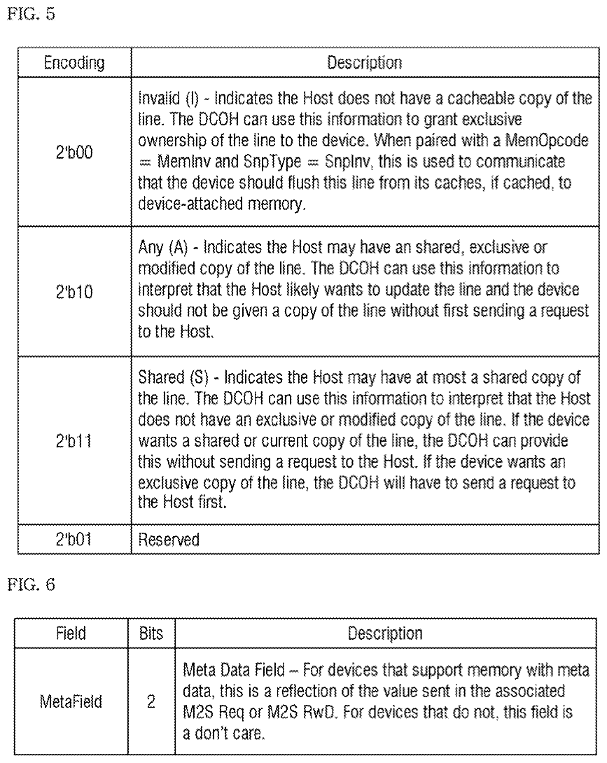

According to some embodiments, the coherency state of the device memory 220, 320 is indicated by the metafield flag as shown in FIG. 5. For example, the invalid state is represented as 2′600, and the exclusive state and the modified state are represented as 2′b10. The shared state when the host device 10 is not in the exclusive state or the modified state is represented as 2′b11.

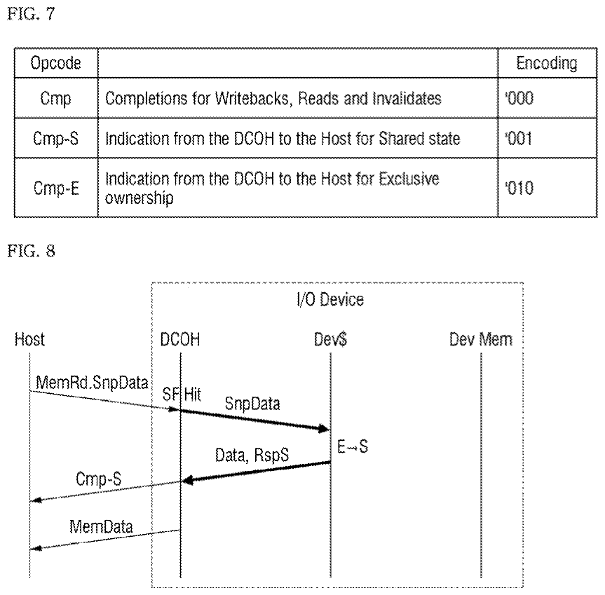

As illustrated in FIG. 7, according to some embodiments, the coherency state of the device memory may be included as the metafield flag in a response transmitted from the host device 10 to the semiconductor device 200, 300. The coherency state of the device memory is one of Cmp, Cmp-S, or Cmp-E. Cmp indicates that writing, reading or invalidation has been completed, Cmp-S indicates the shared state, and Cmp-E indicates the exclusive state.

In FIG. 8, according to some embodiments, when the host device 10 requests to read data (MemRd.SnpData) from the device memory 220, 320, the semiconductor device 200, 300 changes the coherency state of the device memory 220, 320 from the exclusive state to the shared state (E→S) through the DCOH 100, and the device memory 220, 320 transmits, as a response, the requested data together with the coherency state (Data, RspS) to the DCOH 100. The DCOH 100 includes Cmp-S and data of the metafield flag shown in FIG. 7 in the response and transmits it to the host device 10.

In FIG. 9, according to some embodiments, when the host device 10 requests to write data (MemWr.Metavalue) to the device memory 220, 320, the data requested to be written to the device memory 220, 320 is written (write hit), and the semiconductor device 200, 300 transmits through the DCOH 100 a response (Cmp) informing that the coherency state of the device memory 220, 320 corresponds to the writing having been completed. In the host memory, a corresponding data is deleted and the coherency state of the device memory 220, 320 is changed to the exclusive state.

FIG. 10 is a flowchart of an operation between a host device and a semiconductor device, according to some embodiments.

According to some embodiments, as described with reference to FIGS. 3 to 9, when the coherency state of the device memory 220, 320 is shared between the host device and the semiconductor device, the host device controls power being supplied to the device memory by dynamically adjusting the power depending on the coherency state.

More specifically, according to some embodiments, the host device sends a request for the coherency state of the device memory together with an operation control command of the semiconductor device (step S10), and the semiconductor device returns the coherency state of the device memory while operating according to the operation control command (step S20). If none of the coherency states of the device memory are the invalid state, the host device continues to perform a control operation (step S11).

According to some embodiments, if a coherency state of the device memory is the invalid state, i.e., a region is in the invalid state, (step S12) and, if the whole of the device memory is in the invalid state (Whole Region), the host device blocks an operation clock supplied to the device memory (step S23).

According to some embodiments, the host device checks a region that is in the invalid state (step S12), and, if a part of the device memory is in the invalid state (Partial Region), the host device cuts off power supply, reduces a bandwidth, or reduces a clock frequency (step S25) with respect to only the part of the device memory that is in the invalid state.

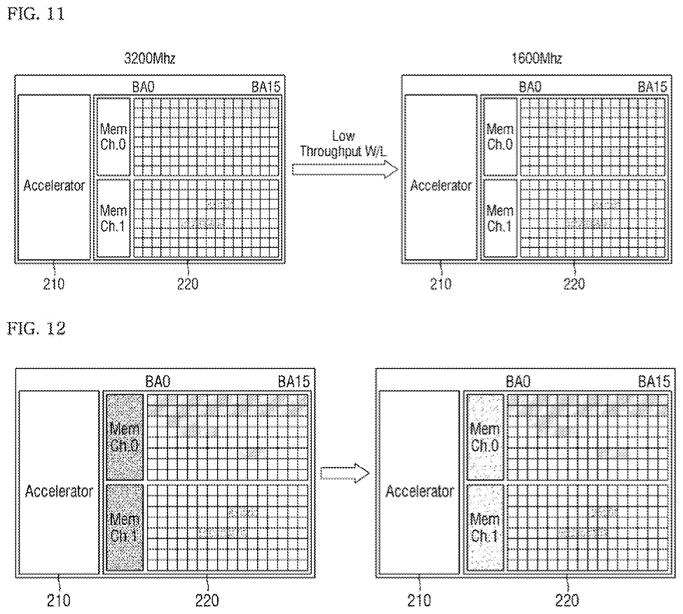

According to some embodiments, the operations of step S23 or step S25 are repeatedly performed until the entire power of the semiconductor device is turned off (step S13), so that the power supplied to the device memory is dynamically adjusted in real time depending on the coherency state. The power supply will be described in detail with reference to FIGS. 11 to 14 below.

FIGS. 11 to 14 illustrate a power operation policy of a semiconductor device, according to some embodiments. In FIGS. 11 to 14, a device on the left represents the semiconductor device before the power supply is changed, and a device on the right represents the semiconductor device after the power supply is changed. For simplicity of description, the semiconductor device 200 that includes the accelerator 210 and the accelerator memory 220 is described as an example in FIGS. 11 to 14, but the scope of the present disclosure is not limited thereto, and the description is applicable to any semiconductor device that includes a device memory to which cache coherency applies.

According to some embodiments, the semiconductor device illustrated in FIGS. 11 to 14 includes the accelerator 210 and the device memory 220, and as described with reference to FIG. 1, further includes the device coherency engine (DCOH) 100 and shares the coherency state of the device memory 220 with the host device 10. According to some embodiments, the device memory 220 includes a plurality of accelerator memories, and each accelerator memory is connected to a plurality of channels. In the illustrated example, it is assumed that the device memory 220 includes a plurality of accelerator memories, each being connected to two channels.

In FIG. 11, according to some embodiments, when a throughput to the accelerator memory decreases (or a workload decreases), that is, when a small data access is performed after a large data access is performed with respect to the accelerator memories of all channels, the semiconductor device 200 reduces the clock frequency to reduce the bandwidth for the device memory 220. For example, the clock frequency supplied to the device memory is reduced from 3200 Mhz to 1600 Mhz.

In FIG. 12, according to some embodiments, both the accelerator memory of Ch.0 and the accelerator memory of Ch.1 may be in the invalid state. However, when only the accelerator memory of some channels Ch.0 is in the invalid state and of the remaining channels, the accelerator memory of Ch.1 is rarely used, the semiconductor device 200 blocks the clock frequency supplied to the accelerator memory of Ch.1 to reduce power consumption for the device memory 220.

According to some embodiments, the semiconductor device informs the host device 10 of the coherency state of each of the plurality of accelerator memories, and independently controls the power supply to each accelerator memory depending on the coherency state of each memory.

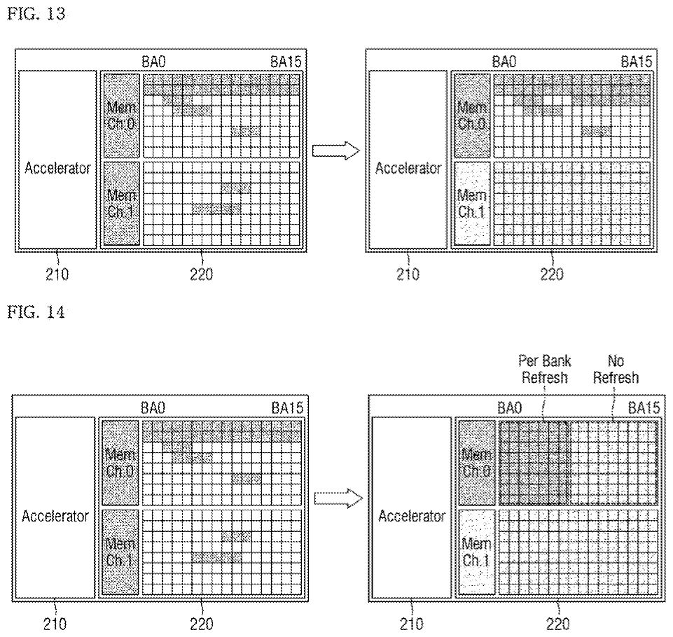

In FIG. 13, according to an embodiment, only a part of the accelerator memory of Ch.0 and a part of the accelerator memory of Ch.1 are in the invalid state. When the accelerator memory of some channels Ch.0 is in a valid state, such as the exclusive, shared, or modified state, and the accelerator memory of the remaining channels Ch.1 are in the invalid state, according to an embodiment, the semiconductor device 200 blocks the clock frequency supplied to the accelerator memory of Ch.1 to reduce power consumption of the device memory 220. Alternatively, according to another embodiment, the semiconductor device 200 turns off the channel of the accelerator memory of Ch.1 to reduce power consumption of the device memory 220.

In FIG. 14, according to still another embodiment, if only a partial area of the accelerator memory of Ch.0 is in a valid state, such as the shared or exclusive state, rather than the invalid state, only an area (Ch.1) in the invalid state performs a refresh operation, and the remaining areas of the accelerator memory of Ch.0 and the accelerator memory of Ch.1 do not perform a refresh operation. Since a reduced area of the memory area is refreshed, power consumption of the device memory 220 is reduced.

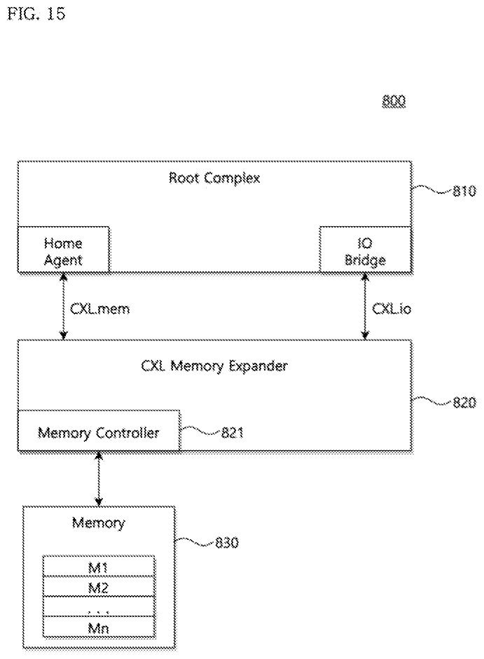

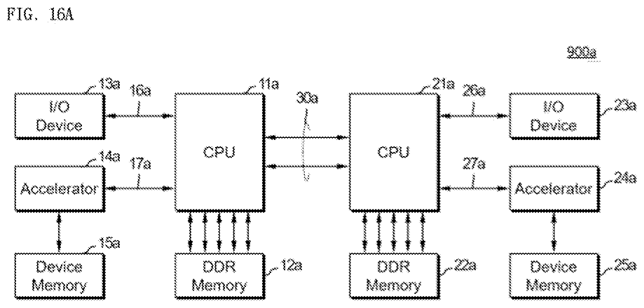

FIG. 15 is a block diagram of a system according to another exemplary embodiment of the present disclosure.

Referring to FIG. 15, according to an embodiment, a system 800 includes a root complex 810, a CXL memory expander 820 connected to the root complex 810, and a memory 830. The root complex 810 includes a home agent and an input/output bridge. The home agent communicates with the CXL memory expander 820 based on a memory protocol CXL.mem, and the input/output bridge communicates with the CXL memory expander 820 based on an inconsistent protocol CXL.io. On the basis of the CXL.mem protocol, the home agent corresponds to a host side agent that is deployed to resolve the overall coherency of the system 800 for a given address.

According to an embodiment, the CXL memory expander 820 includes a memory controller 821. The memory controller 821 performs the operations of the memory controller 310 of FIG. 2 described above with reference to FIGS. 1 to 14.

Further, according to an embodiment of the present disclosure, the CXL memory expander 820 outputs data to the root complex 810 through the input/output bridge based on the inconsistent protocol CXL.io or a PCIe similar thereto.

According to an embodiment, the memory 830 includes a plurality of memory areas M1 to Mn, and each of the memory areas M1 to Mn is implemented as various units of memory. As an example, when the memory 830 includes a plurality of volatile or nonvolatile memory chips, the unit of each of the memory areas M1 to Mn is a memory chip. Alternatively, the memory 830 is implemented such that the unit of each of the memory areas M1 to Mn has a different size, such as a semiconductor die, a block, a bank, or a rank, defined in the memory.

According to an embodiment, the plurality of memory areas M1 to Mn have a hierarchical structure. For example, a first memory area M1 is a high-level memory, and an nth memory area Mn is a low-level memory. The higher-level memory has a relatively small capacity and a faster response speed, and the lower-level memory has a relatively large capacity and a slower response speed. Due to this difference, the minimum achievable latency or maximum latency or maximum error correction level differs for each memory area.

Accordingly, according to an embodiment, the host sets an error correction option for each memory area M1 to Mn. In this case, the host transmits a plurality of error correction option setting messages to the memory controller 821. The error correction option setting messages each include a reference latency, a reference error correction level, and an identifier that identifies a memory area. Accordingly, the memory controller 821 checks the memory area identifier of the error correction option setting messages and sets the error correction option for each memory area M1 to Mn.

As another example, according to an embodiment, a variable ECC circuit or a fixed ECC circuit performs the error correction operation depending on a memory area in which data to be read has been stored. For example, data of high importance may be stored in a high-level memory, and accuracy is given more weight than latency. Accordingly, for data stored in the high-level memory, a variable ECC circuit operation is omitted, and a fixed ECC circuit performs the error correction operation. As another example, data of low importance is stored in a low-level memory. For data stored in the low-level memory, latency is given more weight than accuracy, so that a fixed ECC circuit operation is omitted. That is, in response to a read request, the read data is immediately transmitted to the host without error correction performed by a variable ECC circuit. Depending on the importance of the data and the memory area in which the data has been stored, the selective and parallel error correction operations can be performed in various ways and are not limited to an above-described embodiment.

According to an embodiment, the memory area identifier is also included in a response message of the memory controller 821. A read request message includes an address of data to be read and a memory area identifier. The response message includes a memory area identifier for a memory area that includes the read data.

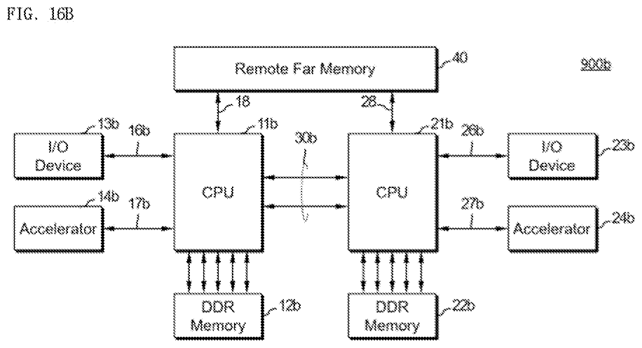

FIGS. 16A and 16B are block diagrams of examples of a system according to an embodiment of the present disclosure.

Specifically, according to an embodiment, the block diagrams of FIGS. 16A and 16B show systems 900a and 900b that include multiple CPUs. Hereinafter, in a description with reference to FIGS. 16A and 16B, repeated descriptions of components described above are omitted.

Referring to FIG. 16A, according to an embodiment, the system 900a includes first and second CPUs 11a and 21a, and first and second double data rate (DDR) memories 12a and 22a connected to the first and second CPUs 11a and 21a, respectively. The first and second CPUs 11a and 21a are connected to each other through an interconnection system 30a based on a processor interconnection technique. As shown in FIG. 16A, the interconnection system 30a provide at least one consistent CPU-to-CPU link.

According to an embodiment, the system 900a includes a first input/output device 13a and a first accelerator 14a that communicate with the first CPU 11a, and a first device memory 15a connected to the first accelerator 14a. The first CPU 11a and the first input/output device 13a communicate with each other through a bus 16a, and the first CPU 11a and the first accelerator 14a communicate with each other through a bus 17a. In addition, the system 900a includes a second input/output device 23a and a second accelerator 24a that communicate with the second CPU 21a, and a second device memory 25a connected to the second accelerator 24a. The second CPU 21a and the second input/output device 23a communicate with each other through a bus 26a, and the second CPU 21a and the second accelerator 24a communicate with each other through a bus 27a.

According to an embodiment, the communication through the buses 16a, 17a, 26a, and 27a is based on a protocol, and the protocol supports the selective and parallel error correction operations described above. Accordingly, the latency required for the error correction operation for the memory, e.g., the first device memory 15a, the second device memory 25a, the first DDR memory 12a and/or the second DDR memory 22a, is reduced, and the performance of system 900a is improved.

Referring to FIG. 16B, according to an embodiment, similar to the system 900a of FIG. 16a, the system 900b includes first and second CPUs 11b and 21b, first and second DDR memories 12b and 22b, first and second input/output devices 13b and 23b, and first and second accelerators 14b and 24b, and further includes a remote far memory 40. The first and second CPUs 11b and 21b communicate with each other through an interconnection system 30b. The first CPU 11b is connected to the first input/output device 13b and the first accelerator 14b through buses 16b and 17b, respectively. The second CPU 21b is connected to the second input/output device 23b and the second accelerator 24b through buses 26b and 27b, respectively.

According to an embodiment, the first and second CPUs 11b and 21b are connected to the remote far memory 40 through first and second buses 18 and 28, respectively. The remote far memory 40 is used for memory expansion in the system 900b, and the first and second buses 18 and 28 are used as memory expansion ports. A protocol that corresponds to the first and second buses 18 and 28 as well as the buses 16b, 17b, 26b, and 27b also supports the selective and parallel error correction operations described above. Accordingly. latency for error correction for the remote far memory 40 is reduced, and the performance of the system 900b is improved.

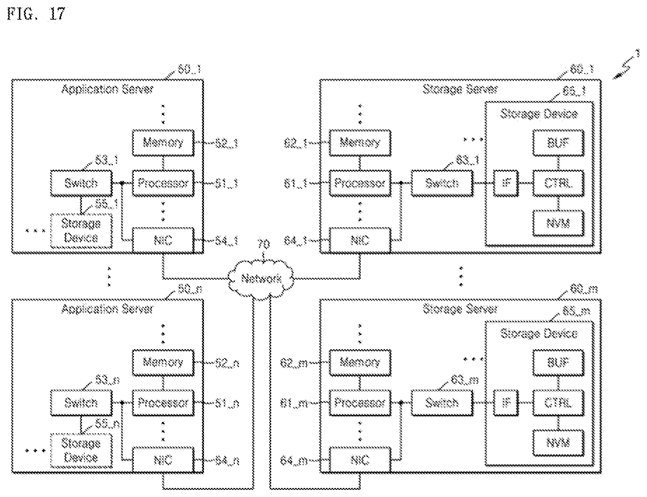

FIG. 17 is a block diagram of a data center that includes a system according to an exemplary embodiment of the present disclosure.

In some embodiments, a system described above is included in a data center 1 as an application server and/or a storage server. In addition, embodiments related to the selective and parallel error correction operations of the memory controller of embodiments of the present disclosure also apply to each of the application server and/or the storage server.

Referring to FIG. 17, according to an embodiment, the data center 1 collects various data and provides services, and is referred to as a data storage center. For example, the data center 1 may be a system that operates a search engine and a database, or may be a computing system used in a government institution or a business such as a bank. As illustrated in FIG. 17, the data center 1 includes application servers 50_1 to 50_n and storage servers 60_1 to 60_m, where m and n are integers greater than 1. The number n of the application servers 50_1 to 50_n and the number m of the storage servers 60_1 to 60_m can vary according to an embodiment, and the number n of the application servers 50_1 to 50_n can differ from the number m of the storage servers 60_1 to 60_m.

According to an embodiment, each application server 50_1 to 50_n includes at least one of a processor 51_1 to 51_n, a memory 52_1 to 52_n, a switch 53_1 to 53_n, a network interface controller (NIC) 54_1 to 54_n, or a storage device 551 to 55_n. The processor 51_1 to 51_n controls the overall operation of the application server 50_1 to 50_n, and accesses the memory 52_1 to 52_n to execute instructions and/or data loaded in the memory 52_1 to 52_n. The memory 521 to 52_n may be, as a non-limiting example, a double data rate synchronous DRAM (DDR SDRAM), a high bandwidth memory (HBM), a hybrid memory cube (HMC), a dual in-line memory module (DIMM), an Optane DIMM or a non-volatile DIMM (NVMDIMM).

According to an embodiment, the number of processors and the number of memories in the application server 50_1 to 50_n may vary. In some embodiments, the processors 51_1 to 51_n and the memories 52_1 to 52_n are provided as processor-memory pairs. In some embodiments, the number of the processors 51_1 to 51_n and the number of the memories 52_1 to 52_n differ. The processors 51_1 to 51_n may include a single-core processor or a multi-core processor. In some embodiments, as shown by a dotted line in FIG. 17, the storage devices 55_1 to 55_n are omitted in the application servers 50_1 to 50_n. The number of the storage devices 55_1 to 55_n in the application servers 50_1 to 50_n can vary according to an embodiment. The processor 51_1 to 51_n, the memories 52_1 to 52_n, the switches 53_1 to 53_n, the NICs 54_1 to 54_n, and/or the storage devices 55_1 to 55_n communicate with each other through a link as described above.

According to an embodiment, the storage server 60_1 to 60_m includes at least one of a processor 61_1 to 61_m, memory 62_1 to 62_m, a switch 63_1 to 63_m, an NIC 64_1 to 64_n, or a storage device 65_1 to 65_m. The processor 61_1 to 61_m and the memory 62_1 to 62_m operate similar to the processor 51_1 to 51_n and the memory 52_1 to 52_n of the application server 50_1 to 50_n described above.

According to an embodiment, the application servers 50_1 to 50_n and the storage servers 60_1 to 60_m communicate with each other through a network 70. In some embodiments, the network 70 is implemented using a Fibre Channel (FC), an Ethernet, etc. The FC is used for relatively high-speed data transmission, and uses an optical switch that provides high performance/high availability. The storage servers 60_1 to 60_m are provided as file storage, block storage, or object storage according to an access method of the network 70.

In some embodiments, the network 70 is a storage-only network, such as a storage area network (SAN). For example, an SAN uses an FC network and is an FC-SAN implemented according to a FC Protocol (FCP). Alternatively, the SAN is an IP-SAN that uses a TCP/IP network and is implemented according to an iSCSI protocol, such as an SCSI over TCP/IP or an Internet SCSI. In some embodiments, the network 70 may be a generic network such as the TCP/IP network. For example, the network 70 is implemented according to a protocol such as FC over Ethernet (FCoE), a network attached storage (NAS), a NVMe over Fabrics (NVMe-oF), etc.

In the following, the application server 501 and the storage server 60_1 are described, but it is noted that the description of the application server 50_1 also applies to another application server (e.g., 50_n), and the description of the storage server 60_1 also applies to another storage server (e.g., 60_m).

In an embodiment, the application server 50_1 stores data requested to be stored by a user or client in one of the storage servers 60_1 to 60_m through the network 70. In addition, the application server 50_1 acquires data requested to be read by the user or client from one of the storage servers 60_1 to 60_m through the network 70. For example, the application server 50_1 is implemented as a web server, a database management system (DBMS), etc.

In an embodiment, the application server 50_1 accesses the memory 52_n and/or the storage device 55_n included in another application server 50_n through the network 70, and/or accesses the memories 62_1 to 62_m and/or the storage devices 65_1 to 65_m in the storage servers 60_1 to 60_m through the network 70. Accordingly, the application server 501 performs various operations on data stored in the application servers 50_1 to 50_n and/or the storage servers 60_1 to 60_m. For example, the application server 50_1 executes an instruction to move or copy data between the application servers 50_1 to 50_n and/or the storage servers 60_1 to 60_m. Data is transferred from the storage devices 65_1 to 65_m of the storage servers 60_1 to 60_m to the memories 52_1 to 52_n of the application servers 50_1 to 50_n directly or through the memories 62_1 to 62_m of the storage servers 60_1 to 60_m. In some embodiments, the data moving through the network 70 is encrypted for security or privacy.

In an embodiment, the storage device 65_1tp 65_m includes an interface IF, a controller CTRL, a non-volatile memory NVM, and a buffer BUF. In the storage server 60_1, the interface IF provides a physical connection between the processor 61_1 and the controller CTRL and a physical connection between the NIC 64_1 and the controller CTRL. For example, the interface IF is implemented in a direct attached storage (DAS) method in which the storage device 65_1 is directly connected by a dedicated cable. In addition, for example, the interface (IF) may be one of various types of interfaces, such as an advanced technology attachment (ATA), a serial ATA (SATA), an external SATA (e-SATA), a small computer small interface (SCSI), a serial attached SCSI (SAS), a peripheral component interconnection (PCI), a PCI express (PCIe), an NVM express (NVMe), an IEEE 1394, a universal serial bus (USB), a secure digital (SD) card, a multi-media card (MMC), an embedded multi-media card (eMMC), a universal flash storage (UFS), an embedded universal flash storage (eUFS), or a compact flash (CF) card.

In an embodiment, in the storage server 60_1, the switch 63_1 selectively connects the processor 61_1 to the storage device 65_1, or selectively connects the NIC 64_1 to the storage device 65_1, under the control of the processor 61_1.

In some embodiments, the NIC 64_1 is one of a network interface card, a network adapter, etc. The NIC 64_1 may be connected to the network 70 through a wired interface, a wireless interface, a Bluetooth interface, an optical interface, etc. The NIC 64_1 includes an internal memory, a digital signal processor (DSP), a host bus interface, etc., and is connected to the processor 61_1 and/or the switch 63_1 through the host bus interface. In some embodiments, the NIC 64_1 is integrated with at least one of the processor 61_1, the switch 63_1, or the storage device 65_1.

In an embodiment, in the application server 50_1 to 50_n or the storage server 60_1 to 60_m, the processor 51_1 to 51_n, 61_1 to 61_m sends a command to the storage device 55_1 to 55_n and 65_1 to 65_m or the memory 521 to 52_n, 62_1 to 62_m to program or read data. In this case, the data may have been error-corrected through an error correction code (ECC) engine. The data is data processed by data bus inversion (DBI) or data masking (DM), and may include cyclic redundancy code (CRC) information. The data may be encrypted for security or privacy.

In an embodiment, the storage device 55_1 to 55_n, 65_1 to 65_m transmits a control signal and a command/address signal to the nonvolatile memory device NVM, such as a NAND flash memory device, in response to a read command received from the processor 51_1 to 51_n, 61_1 to 61_m. Accordingly, when data is read from the nonvolatile memory device NVM, a read enable signal is transmitted as a data output control signal and outputs data to a DQ bus. A data strobe signal is generated by using the read enable signal. The command and address signal are latched by a rising edge or a falling edge of a write enable signal.

In an embodiment, the controller CTRL controls the overall operation of the storage device 65_1. In an embodiment, the controller CTRL includes a static random access memory (SRAM). The controller CTRL writes data to the nonvolatile memory device NVM in response to a write command, or reads data from the nonvolatile memory device NVM in response to a read command. For example, the write command and/or the read command are generated based on a request provided from the host, e.g., the processor 61_1 in the storage server 60_1, the processor 61_m in another storage server 60_m, or the processor 51_1 to 51_n in the application server 50_1 to 50_n. The buffer BUF temporarily stores (buffers) data to be written to the nonvolatile memory device NVM or data read from the nonvolatile memory device NVM. In some embodiments, the buffer BUF includes a DRAM. In addition, the buffer BUF stores metadata, and the metadata refers to user data or data generated by the controller CTRL to manage the nonvolatile memory device NVM. The storage device 65_1 includes a secure element for security or privacy.

In concluding the detailed description, those skilled in the art will appreciate that many variations and modifications can be made to embodiments without substantially departing from the principles of the present disclosure. Therefore, embodiments are used in a generic and descriptive sense only and not for purposes of limitation.

1. A semiconductor device, comprising:
a device memory; and
a device coherency engine (DCOH) that shares a coherency state of the device memory based on data in a host device and a host memory,
wherein a power supply of the device memory is dynamically adjusted based on the coherency state.

2. The semiconductor device of claim 1, wherein the DCOH is included in an accelerator or a memory controller connected between the device memory and the host device.

3. The semiconductor device of claim 1, wherein the coherency state of the device memory includes an invalid state, a shared state, a modified state, and an exclusive state.

4. The semiconductor device of claim 3, wherein when the entire device memory is in the invalid state, the power supply of the device memory is cut off.

5. The semiconductor device of claim 3, wherein when the coherency state is the invalid state, an operation clock supplied to the device memory is blocked.

6. The semiconductor device of claim 1, wherein an operating frequency of the device memory is dynamically adjusted according to a state of data transmission/reception to/from the device memory.

7. The semiconductor device of claim 3, wherein the device memory includes a plurality of device memories, wherein each of the plurality of device memories is connected to a plurality of channels, and
the power supply of each device memory of the plurality of device memories is independently controlled according to the coherency state for each device memory of the plurality of device memories.

8. The semiconductor device of claim 7, wherein when some of the plurality of device memories are in the invalid state,
the power supply is cut off to the device memories of the plurality of device memories that are in the invalid state.

9. The semiconductor device of claim 8, wherein a channel of each of the plurality of device memories that are in the invalid state is turned off.

10. The semiconductor device of claim 8, wherein when only a partial area of the device memory is in a valid state,
only an area in the invalid state is refreshed by a refresh operation, and remaining areas of the device memory are not refreshed by the refresh operation.

11. The semiconductor device of claim 1, wherein the coherency state is shared by a metafield signal between the host device and the DCOH.

12. A computing system, comprising:
a semiconductor device connected to a host device through a Compute eXpress Link (CXL) interface, wherein the semiconductor device comprises:
at least one accelerator memory that stores data; and
an accelerator that shares a coherency state of the at least one accelerator memory with the host device,
wherein a power supply to the accelerator memory is dynamically controlled by the semiconductor device according to the coherency state.

13. The computing system of claim 12, wherein the coherency state of the at least one accelerator memory includes an invalid state, a shared state, a modified state, and an exclusive state.

14. The computing system of claim 13, wherein when the entire accelerator memory is in the invalid state, the power supply to the accelerator memory is cut off.

15. The computing system of claim 13, wherein when only a partial area of the accelerator memory is used, a bandwidth of the accelerator memory is dynamically adjusted.

16. The computing system of claim 13, wherein when some of a plurality of accelerator memories are in the invalid state,
the power supply to the accelerator memories that are in the invalid state is cut off.

17. The computing system of claim 16, wherein a channel of each of the accelerator memories in the invalid state is turned off.

18. The computing system of claim 16, wherein when only a partial area of the accelerator memory is in a valid state,
only an area in the invalid state is refreshed by a refresh operation, and remaining areas of the device memory are not refreshed by the refresh operation.

19. A semiconductor device connected to a host device, comprising:
a memory device that includes at least one working memory that store data; and
a memory controller that shares a coherency state of the working memory with the host device,
wherein a power supply to the working memory is dynamically controlled by the semiconductor device according to the coherency state.

20. The semiconductor device of claim 19, wherein the memory controller shares the coherency state of the working memory through a metafield flag.

21-24. (canceled)
